(19) United States
(12) Patent Application Publication
(10) Pub. No.: US 2004/0192008 A1
(43) Pub. Date: Sep. 30, 2004

(54) Semiconductor device including interconnection and capacitor, and method of manufacturing the same

(75) Inventor: Takeshi Matsunuma, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/653,214

(22) Filed: Sep. 3, 2003

(30) Foreign Application Priority Data
Mar. 27, 2003 (JP) 2003-087436(P)

(51) Int. Cl. H01L 21/20

(52) U.S. Cl. 438/393; 438/396

(57) ABSTRACT

A method of manufacturing a semiconductor device including an interconnection and a capacitor formed with a Cu layer in accordance with the present invention includes the steps of forming an interlayer insulation layer, forming an interconnection hole and a capacitor hole in the interlayer insulation layer, filling the interconnection hole with the Cu layer to form an interconnection layer, and partly filling the capacitor hole with the Cu layer to form one electrode of the capacitor. The step of filling the interconnection hole with the Cu layer to form the interconnection layer and the step of partly filling the capacitor hole with the Cu layer to form one electrode of the capacitor are performed in a single process step. Thus, manufacturing process of the semiconductor device can be simplified.

### BACKGROUND OF THE INVENTION

1. Field of the Invention

The present invention relates to a semiconductor device and a method of manufacturing the same. More particularly, the present invention relates to a semiconductor device including an interconnection formed of a conductor containing copper and a capacitor, and to a method of manufacturing the same.

2. Description of the Background Art

In LSIs (Large Scale Integrated Circuits) such as microprocessors and memories, which are known as typical semiconductor devices, further reduction in dimensions of individual elements such as a capacitor has been being achieved as integration density is increased. Accordingly, size reduction has also been being promoted for interconnections connecting the elements, decreasing the cross-sectional area of the interconnections. As the cross-sectional area of an interconnection decreases, the interconnection will have a higher resistance value. Thus, there is a tendency that interconnections using Cu (copper) based metals, which have lower resistance values, are employed instead of conventional Al (aluminum) based metals.

A method of manufacturing a semiconductor device including an interconnection using such a Cu based metal and a capacitor is disclosed, for example, in Japanese Patent Laying-Open No. 2001-313373. The method of manufacturing a semiconductor device disclosed in the above publication is set forth below.

A via for forming a portion other than a capacitor portion and a via and a trench for forming the capacitor portion are formed in an insulation layer. Next, a barrier layer and a dielectric layer are deposited over these vias and trench. This barrier layer is identified as a lower electrode of the capacitor. A photoresist is then patterned onto the dielectric layer at the capacitor portion to etch the dielectric layer at the portion other than the capacitor portion, and the barrier layer at the portion other than the capacitor portion is exposed. Next, the photoresist over the dielectric layer at the capacitor portion is removed, and a barrier layer and a Cu layer are deposited over the barrier layer at the portion other than the capacitor portion, the dielectric layer at the capacitor portion, and other exposed surfaces. Thereafter, CMP (Chemical Mechanical Polish) is performed to remove excess portions of the barrier layer, the dielectric layer, and the Cu layer over the insulation layer, thus manufacturing a semiconductor device including a capacitor. Another method of manufacturing a semiconductor device including an interconnection using a Cu based metal and a capacitor is disclosed, for example, in Japanese Patent Laying-Open No. 2001-177076.

However, using the above-mentioned method to manufacture a semiconductor device including an interconnection of a Cu based metal and a capacitor requires at least the steps of forming a lower electrode of the capacitor and a barrier metal layer at the interconnection portion, forming a dielectric layer of the capacitor, removing a dielectric layer formed over the barrier metal layer at the interconnection portion, forming a Cu layer which will be an interconnection layer and the other electrode of the capacitor, removing an excess portion of the Cu layer over the interconnection layer, and forming a barrier layer over the interconnection layer. Thus, there has been a problem that the manufacturing process is lengthy. This problem requires extra cost and manufacturing time.

### SUMMARY OF THE INVENTION

It is an object of the present invention to provide a semiconductor device which can simplify manufacturing process and a method of manufacturing the same.

The present invention provides a method of manufacturing a semiconductor device including an interconnection formed of a conductor containing copper and a capacitor. The method includes the steps of forming a first insulation layer, forming an interconnection hole and a capacitor hole in the first insulation layer, filling the interconnection hole with a conductor containing copper to form an interconnection layer, and partly filling the capacitor hole with the conductor containing copper to form one electrode of the capacitor. The step of filling the interconnection hole with the conductor containing copper to form the interconnection layer and the step of partly filling the capacitor hole with the conductor containing copper to form one electrode of the capacitor are performed in a single process step.

According to the method of manufacturing a semiconductor device of the present invention, a first copper layer which will be the interconnection layer and the first copper layer which will be one electrode of the capacitor are formed in a single process step. Thus, the method of manufacturing a semiconductor device is more simplified than in the case that a copper layer which will be an interconnection layer and a copper layer which will be one electrode of the capacitor are formed in separate process steps. In addition, a conductive layer other than of copper can be used for an upper interconnection.

A semiconductor device in accordance with one aspect of the present invention is a semiconductor device including an interconnection and a capacitor, wherein the interconnection and one electrode of the capacitor are both formed of a conductor containing copper, and a barrier layer formed to cover the interconnection and a dielectric layer of the capacitor are formed with a single layer.

According to the semiconductor device of the present aspect, the interconnection and one electrode of the capacitor are both formed in a single process step, and the barrier layer and the dielectric layer of the capacitor are formed in a single process step. Therefore, it is possible to simplify manufacturing process of the semiconductor device.

A semiconductor device in accordance with another aspect of the present invention is a semiconductor device including an interconnection and a capacitor, wherein the interconnection and one electrode of the capacitor are both formed of a conductor containing copper, and a barrier layer formed to cover the interconnection and a dielectric layer of the capacitor are formed with layers different from each other.

According to the semiconductor device of the present aspect, the interconnection and one electrode of the capacitor are both formed in a single process step. Therefore, it is possible to simplify manufacturing process of the semiconductor device. In addition, it is possible to form layers suitable for each of the barrier layer and the dielectric layer of the capacitor.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 11B are schematic cross-sectional views showing a method of manufacturing a semiconductor device including an interconnection and a capacitor in accordance with a first embodiment of the present invention, in the order of process steps, wherein FIG. 3B is a schematic cross-sectional view showing another example of the manufacturing process step shown in FIG. 3A, FIG. 4B is a schematic cross-sectional view showing another example of the manufacturing process step shown in FIG. 4A, and FIG. 11B is a schematic cross-sectional view showing another example of the manufacturing process step shown in FIG. 11A.

FIGS. 12 to 17 are schematic cross-sectional views showing a method of manufacturing a semiconductor device including an interconnection and a capacitor in accordance with a second embodiment of the present invention, in the order of process steps.

FIGS. 18 to 23 are schematic cross-sectional views showing a method of manufacturing a semiconductor device including an interconnection and a capacitor in accordance with a third embodiment of the present invention, in the order of process steps.

### DESCRIPTION OF THE PREFERRED EMBODIMENTS

In the following, embodiments of the present invention will be described with reference to the drawings.

First Embodiment

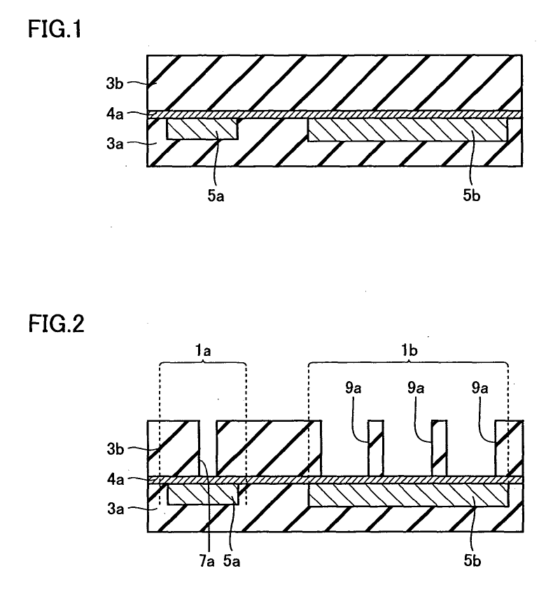

Referring to FIG. 1, lower interconnections 5a and 5b formed of, for example, Cu, are formed in an interlayer insulation layer 3a. Next, a barrier layer 4a and an interlayer insulation layer 3b (a first insulation layer) are stacked on so as to cover interlayer insulation layer 3a and lower interconnections 5a and 5b. Barrier layer 4a is an insulation layer formed to prevent Cu oxidation and diffusion. Interlayer insulation layers 3a and 3b are formed of, for example, SiO₂, SiO, MSQ (methyl silsesquioxane polymer), HSQ (hydrogen silsesquioxane polymer), organic polymer, or the like. Barrier layer 4a is formed of, for example, SiC or SiCN.

Referring to FIG. 2, an interconnection hole 7a and a capacitor hole 9a are opened in interlayer insulation layer 3b such that the upper surface of barrier layer 4a is exposed, by general photolithography and etching techniques. Interconnection hole 7a is opened at an interconnection portion la where an interconnection 23 is to be formed. Capacitor hole 9a is opened at a capacitor portion lb where a capacitor 21 is to be formed. At this stage, interconnection hole 7a and capacitor hole 9a are opened such that the volume of interconnection hole 7a is smaller than the volume of capacitor hole 9a.

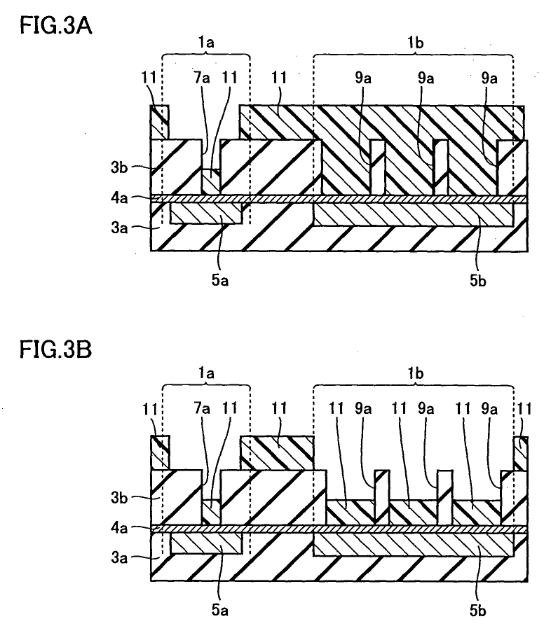

Referring to FIG. 3A, a photoresist 11 is patterned so as to cover a portion other than a portion around interconnection hole 7a.

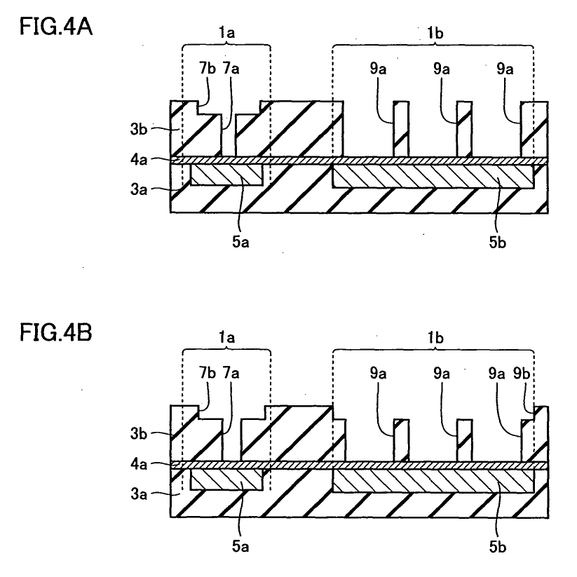

Referring to FIG. 4A, interlayer insulation layer 3b around interconnection hole 7a is etched to a fixed depth to open an interconnection hole 7b. Thereafter, photoresist 11 is removed.

Referring now to FIGS. 3B and 4B, a capacitor hole 9b may be opened together with interconnection hole 7b, by patterning photoresist 11 so as to cover a portion except the portion around interconnection hole 7a and a portion around capacitor hole 9a, and etching interlayer insulation layer 3b around interconnection hole 7a and capacitor hole 9a to a fixed depth.

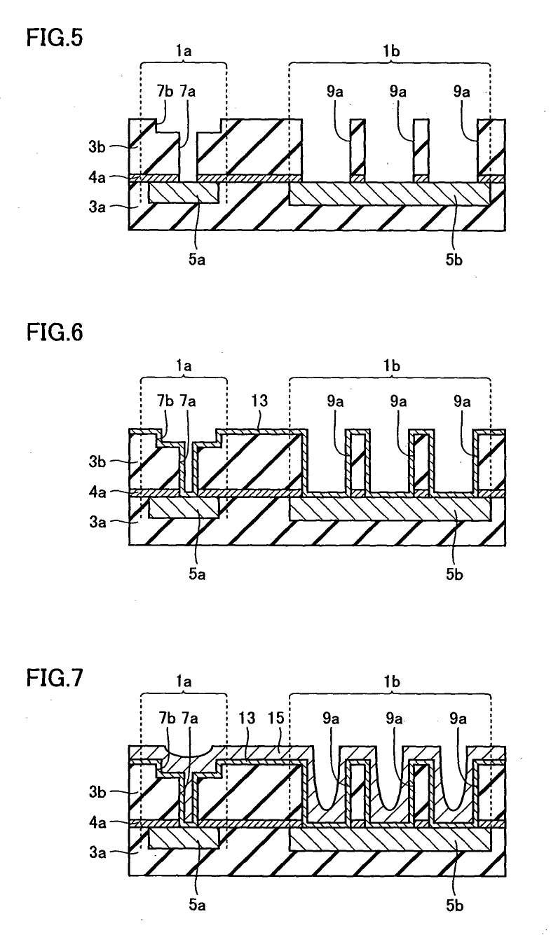

Referring to FIG. 5, barrier layer 4a at the bottoms of interconnection hole 7a and capacitor hole 9a is etched by general photolithography and etching techniques. Thus, lower interconnections 5a and 5b are exposed at the bottoms of interconnection hole 7a and capacitor hole 9a.

Referring to FIG. 6, a barrier metal layer 13 is formed so as to cover the side walls and bottoms of interconnection holes 7a and 7b and capacitor hole 9a, as well as the upper portion of interlayer insulation layer 3b. Barrier metal layer 13 is formed by depositing TaN by means of, for example, CVD (Chemical Vapor Deposition) or sputtering. Barrier metal layer 13 is a conductive layer formed to obtain stable contact with the underlying metal (lower interconnections 5a, 5b).

Referring to FIG. 7, a Cu layer 15 is formed by means of, for example, plating, so as to cover the upper portion of barrier metal layer 13. Here, Cu layer 15 is formed thick enough to completely fill interconnection holes 7a and 7b and to partly fill capacitor hole 9a.

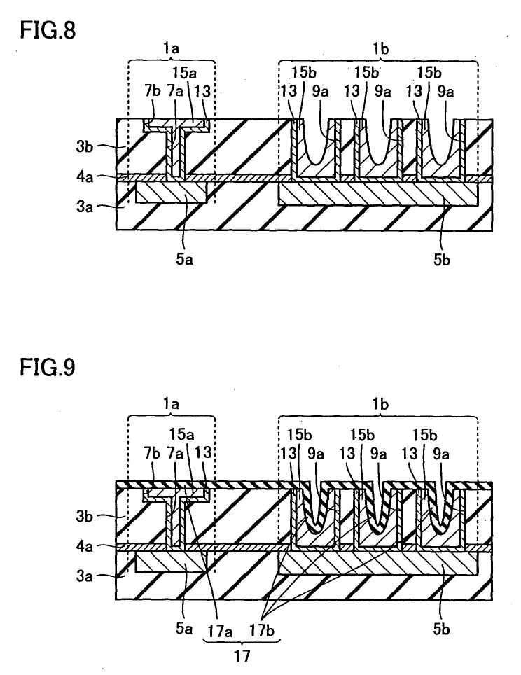

Referring to FIG. 8, portions of Cu layer 15 and barrier metal layer 13 which are located above interlayer insulation layer 3b are removed by means of, for example, CMP (Chemical Mechanical Polish). Thus, Cu layer 15 is divided into a Cu layer 15a at interconnection portion la and a Cu layer 15b at capacitor portion lb. This Cu layer 15a will be an interconnection layer, and Cu layer 15b will be one electrode of the capacitor.

Referring to FIG. 9, a coating layer 17 is formed so as to cover the upper portions of Cu layers 15a, 15b and the upper portion of interlayer insulation layer 3b. Coating layer 17 is formed by depositing SiC or SiCN by means of, for example, CVD. This coating layer 17 will be a barrier layer 17a covering the upper portion of the interconnection layer, and a dielectric layer 17b of the capacitor.

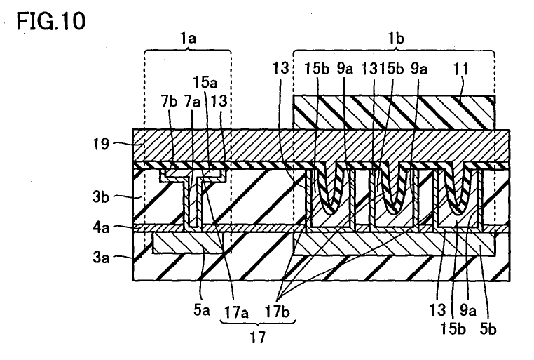

Referring to FIG. 10, a conductive layer 19, which is formed of Al, for example, is formed so as to cover the upper portion of coating layer 17. Then, photoresist 11 is patterned so as to cover capacitor portion lb.

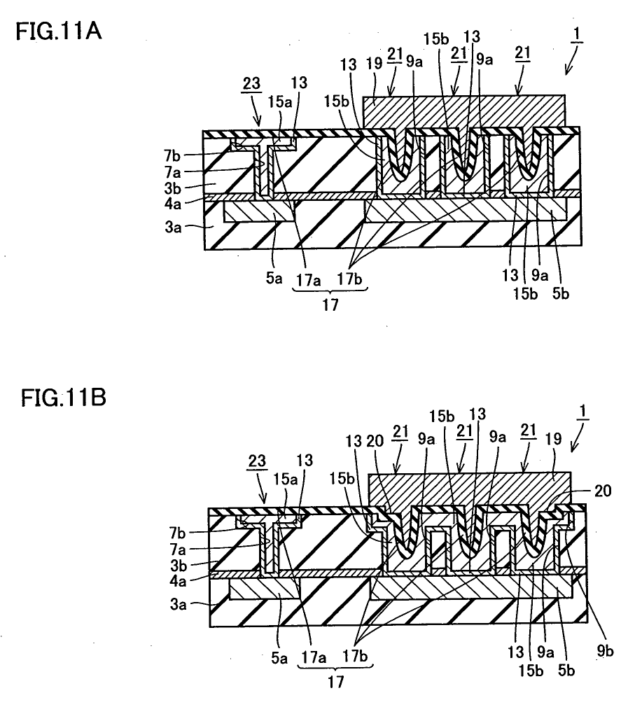

Referring to FIG. 11A, conductive layer 19 at a portion other than capacitor portion 1b is etched, forming the other electrode of the capacitor. Through the above process steps, a semiconductor device 1 including interconnection 23 and capacitor 21 in the present embodiment is obtained.

When capacitor hole 9b is opened together with interconnection hole 7b as shown in FIGS. 3B and 4B, semiconductor device 1 including interconnection 23 and capacitor 2lwill be as shown in FIG. 11B. In this case, the capacitor hole is formed with capacitor hole 9a and capacitor hole 9b which have diameters different from each other. The diameter changes discretely at the boundary between capacitor hole 9a and capacitor hole 9b. Further, capacitor 21 has a step portion 20.

In the present embodiment, interlayer insulation layers 3a and 3b, barrier layers 4a and 4b, and coating layer 17 may each be formed of another insulating material. In addition, lower interconnections 5a and 5b, barrier metal layer 13, and conductive layer 19 may each be formed of another conductor. Further, Cu layer 15 may be formed of any conductive layer containing copper.

According to the method of manufacturing semiconductor device 1 in the present embodiment, the step of forming Cu layer 15a, which will be the interconnection layer, and the step of forming Cu layer 15b, which will be one electrode of capacitor 21, are performed in a single process step. Thus, the method of manufacturing semiconductor device 1 is more simplified than in the case that a Cu layer which will be an interconnection layer and a Cu layer which will be one electrode of a capacitor are formed in separate process steps. In addition, a conductive layer other than of copper can be used for the other electrode of capacitor 21.

Preferably, the above manufacturing method further includes the step of forming coating layer 17 covering Cu layer 15a, which will be the interconnection layer, and Cu layer 15b, which will be one electrode of capacitor 21. Thus, since coating layer 17 which covers the interconnection layer and coating layer 17 which will be the dielectric layer of the capacitor are formed in a single process step, the method of manufacturing semiconductor device 1 is more simplified than in the case that coating layer 17 which covers the interconnection layer and coating layer 17 which will be the dielectric layer of the capacitor are formed in separate process steps.

In the above manufacturing method, coating layer 17 is preferably barrier layer 17a which covers the upper portion of Cu layer 15a. Thus, Cu atoms of Cu layer 15a are prevented from diffusing into interlayer insulation layer.

Semiconductor device 1 of the present embodiment includes interconnection 23 and capacitor 21. Interconnection 23 and one electrode of capacitor 21 are both formed with Cu layer 15, and barrier layer 17a formed to cover interconnection 23 and dielectric layer 17b of capacitor 21 are formed with the same layer. Thus, interconnection 23 and one electrode of capacitor 21 are both formed in a single process step. In addition, barrier layer 17a and dielectric layer 17b of capacitor 21 are formed in a single process step. Therefore, it becomes possible to simplify the manufacturing process of semiconductor device 1.

Semiconductor device 1 of the present embodiment is preferably provided with interconnection holes 7a and 7b in which interconnection 23 has been formed, and capacitor holes 9a and 9b in which capacitor 21 has been formed. In addition, the volume of interconnection holes 7a and 7b is smaller than the volume of capacitor holes 9a and 9b. Thus, it is possible to easily form Cu layer 15 with a thickness which completely fills interconnection holes 7a and 7b and partly fills capacitor holes 9a and 9b, in the process step of filling interconnection holes 7a and 7b with Cu layer 15 to form the interconnection layer, and forming one electrode of the capacitor with Cu layer 15 in capacitor holes 9a and 9b. Therefore, Cu layer 15a, which will be the interconnection layer, and Cu layer 15b, which will be one electrode of capacitor 21, can be formed in a single process step, simplifying the manufacturing process of semiconductor device 1.

In semiconductor device 1 of the present embodiment, the capacitor hole is preferably formed with capacitor hole 9a and capacitor hole 9b which have diameters different from each other. The diameter changes discretely at the boundary between capacitor hole 9a and capacitor hole 9b. Thus, step portion 20 is formed at the boundary between capacitor hole 9a and capacitor hole 9b. As a result, a step is also formed in one electrode of capacitor 21 formed along the inner walls of capacitor holes 9a and 9b, and the area facing toward the other electrode of capacitor 21 is increased by the region of step portion 20.

Second Embodiment

The manufacturing method of the present embodiment initially follows the same manufacturing process steps as those in the first embodiment shown in FIGS. 1 to 9. Thus, the description thereof will not be repeated here.

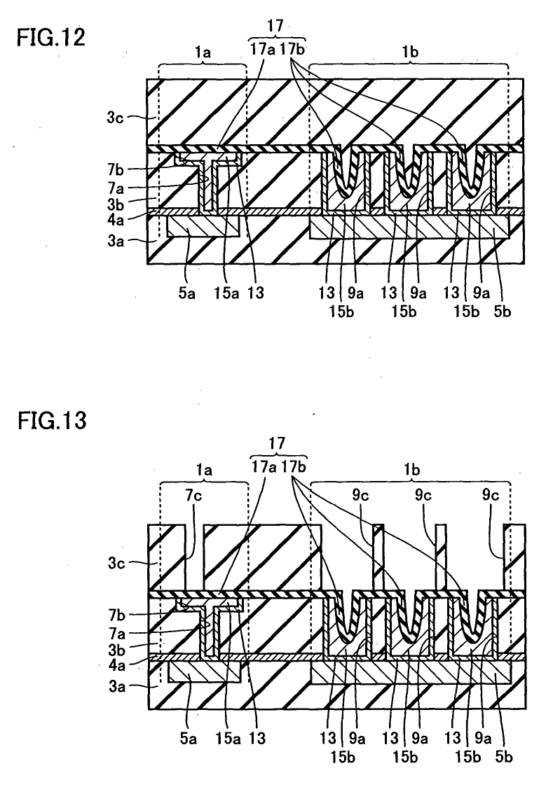

Referring to FIG. 12, an interlayer insulation layer 3c (a second insulation layer) is formed so as to cover the upper portion of coating layer 17.

Referring to FIG. 13, an upper interconnection hole 7c and a hole 9c for forming the other electrode are opened in interlayer insulation layer 3c such that the upper faces of barrier layerl7a and dielectric layer 17b are exposed, by general photolithography and etching techniques.

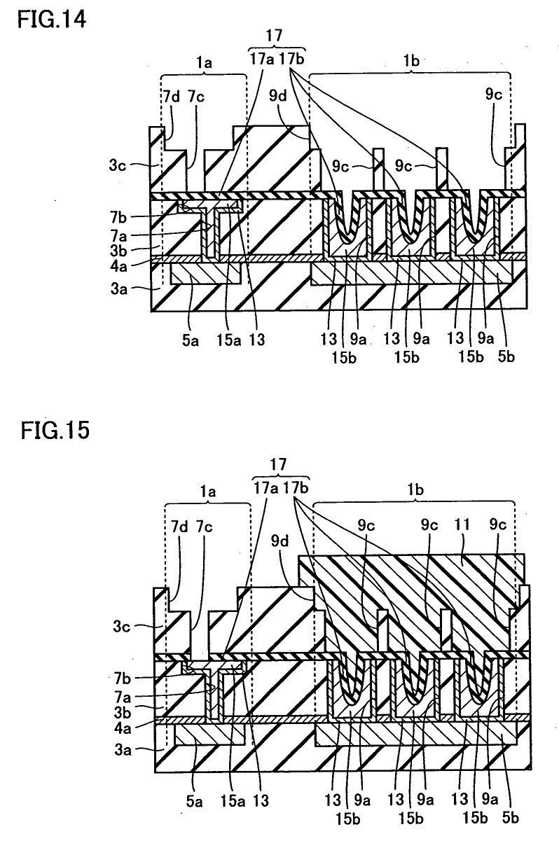

Referring to FIG. 14, an upper interconnection hole 7d and a hole 9d for forming the other electrode are opened in interlayer insulation layer 3c by general photolithography and etching techniques.

Referring to FIG. 15, photoresist 11 is patterned so as to cover a portion around holes 9c and 9d for forming the other electrode, and barrier layer 17a at the bottom of upper interconnection hole 7c is etched. Thus, Cu layer 15a is exposed at the bottom of upper interconnection hole 7c.

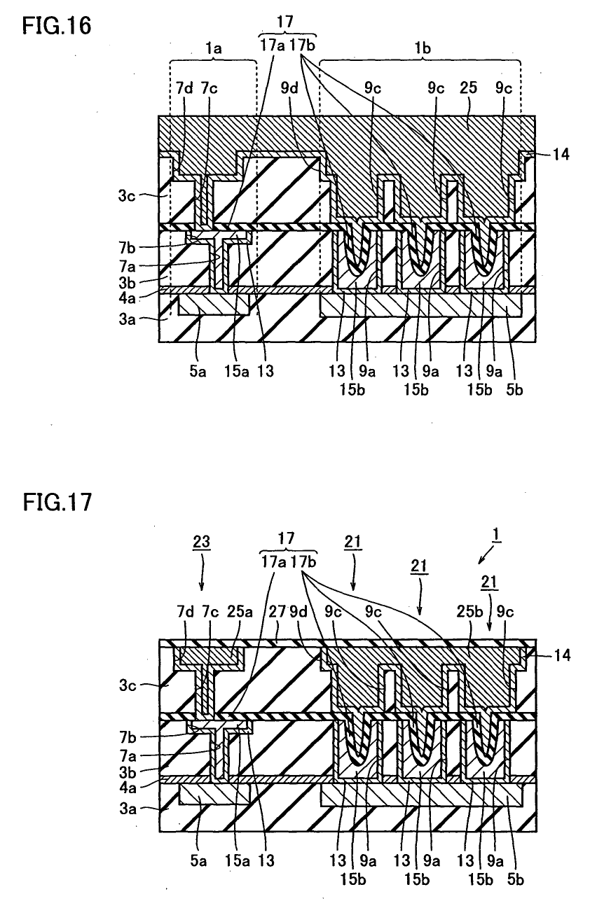

Referring to FIG. 16, after the removal of photoresist 11, a barrier metal layer 14 is formed so as to cover the side walls and bottoms of upper interconnection holes 7c and 7d and the other electrode holes 9c and 9d, as well as the upper portion of interlayer insulation layer 3c. Then, a Cu layer 25 is formed so as to cover the upper portion of barrier metal layer 14. Here, Cu layer 25 is formed thick enough to fill upper interconnection holes 7c and 7d and the other electrode holes 9c and 9d.

Referring to FIG. 17, portions of Cu layer 25 and barrier metal layer 14 which are located above interlayer insulation layer 3c are removed by means of, for example, CMP. Thus, Cu layer 25 is divided into a Cu layer 25a and a Cu layer 25b. This Cu layer 25a will serve as an upper interconnection layer, and Cu layer 25b will serve as the other electrode of the capacitor. Then, a barrier layer 27 is formed so as to cover the upper portions of Cu layers 25a, 25b and interlayer insulation layer 3c. Through the above process steps, semiconductor device 1 including interconnection 23 and capacitor 21 in the present embodiment is obtained.

In the present embodiment, when forming Cu layer 25a, which will be the upper interconnection, over Cu layer 15a, which will be the interconnection layer, Cu layer 25a, serving as the upper interconnection, and Cu layer 25b, serving as the other electrode of capacitor 21, are formed in a single process step. Therefore, the method of manufacturing semiconductor device 1 is more simplified than in the case that a copper layer which will be an upper interconnection layer and a copper layer which will be the other electrode of a capacitor are formed in separate process steps.

Third Embodiment

The manufacturing method of the present embodiment initially follows the same manufacturing process steps as those in the first embodiment shown in FIGS. 1 to 7. Thus, the description thereof will not be repeated here.

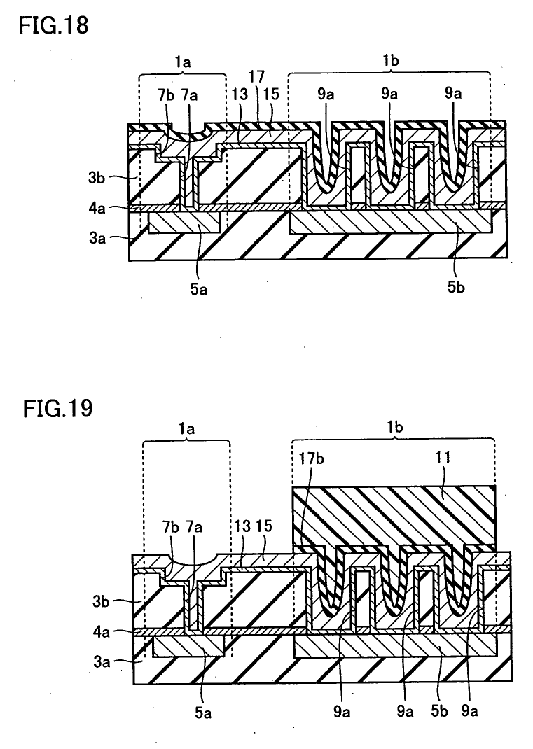

Referring to FIG. 18, coating layer 17 is formed so as to cover the upper portion of Cu layer 15.

Referring to FIG. 19, photoresist 11 is patterned so as to cover capacitor portion 1b. Then, coating layer 17 at the portion other than capacitor portion 1b is etched, exposing Cu layer 15 at the portion other than capacitor portion 1b. Coating layer 17 remained at capacitor portion lb will serve as dielectric layer 17b of the capacitor.

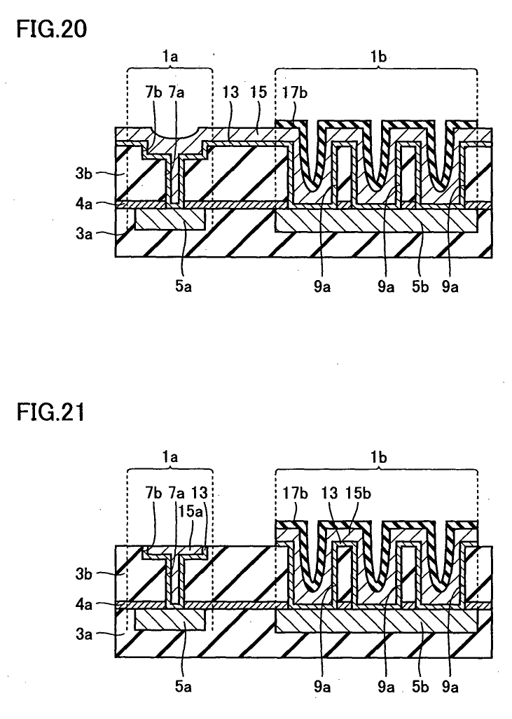

Referring to FIG. 20, photoresist 11 is removed.

Referring to FIG. 21, Cu layer 15 and barrier metal layer 13 at a portion not covered with dielectric layer 17b of the capacitor are removed by means of, for example, CMP. Thus, Cu layer 15 is divided into Cu layer 15a at interconnection portion la and Cu layer 15b at capacitor portion lb. This Cu layer 15a will be the interconnection layer, and Cu layer 15b will be one electrode of the capacitor.

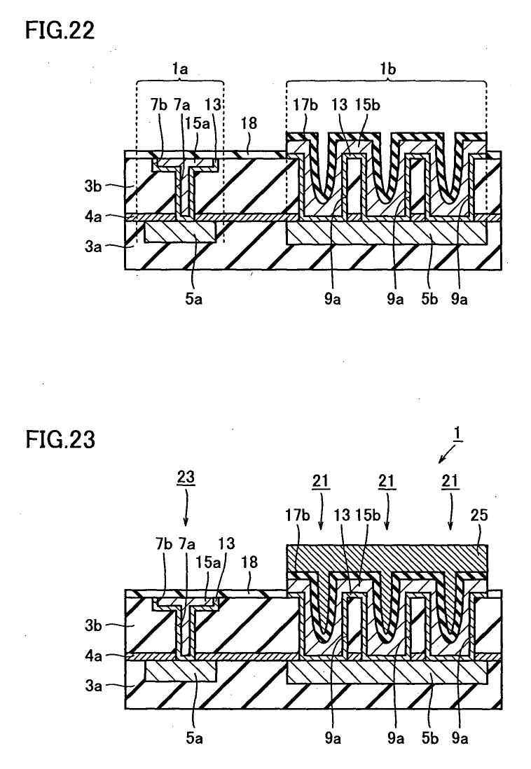

Referring to FIG. 22, a barrier layer 18 is formed so as to cover the upper portion of interlayer insulation layer 3b and the upper portion of dielectric layer 17b of the capacitor. Then, barrier layer 18 over dielectric layer 17b of the capacitor is etched by general photolithography and etching techniques.

Referring to FIG. 23, conductive layer 25 is formed so as to cover the upper portion of barrier layer 18 and the upper portion of dielectric layer 17b of the capacitor. Then, conductive layer 25 at the portion other than capacitor portion 1b is etched by general photolithography and etching techniques, thereby forming the other electrode of the capacitor. Through the above process steps, semiconductor device 1 including interconnection 23 and capacitor 21 in the present embodiment is obtained.

In the present embodiment, the step of removing coating layer 17 covering the portion which will be Cu layer 15a, and the step of forming barrier layer 18 covering Cu layer 15a are further included. Thus, barrier layer 18 covering Cu layer 15a and dielectric layer 17b of the capacitor are formed in separate process steps, allowing the formation of layers suitable for each of barrier layer 18 and dielectric layer 17b of the capacitor.

Semiconductor device 1 of the present embodiment includes interconnection 23 and capacitor 21. Interconnection 23 and one electrode of capacitor 21 are both formed with Cu layer 15, and barrier layer 18 formed to cover interconnection 23 and dielectric layer 17b of capacitor 21 are formed with layers different from each other. Thus, it becomes possible to form layers suitable for each of barrier layer 18 and dielectric layer 17b of the capacitor.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of forming a semiconductor device including an interconnection formed of a conductor containing copper and a capacitor, comprising the steps of:
forming a first insulation layer;
forming an interconnection hole and a capacitor hole in said first insulation layer;
filling said interconnection hole with the conductor containing copper to form an interconnection layer; and
partly filling said capacitor hole with the conductor containing copper to form one electrode of said capacitor,
wherein said step of filling said interconnection hole with the said conductor containing copper to form said interconnection layer and said step of partly filling said capacitor hole with the said conductor containing copper to form one electrode of said capacitor are performed in a single process step.

2. The method of manufacturing a semiconductor device according to claim 1, further comprising the step of forming a coating layer covering said interconnection layer and one electrode of said capacitor.

3. The method of manufacturing a semiconductor device according to claim 2, wherein said coating layer covering said interconnection layer is a barrier layer.

4. The method of manufacturing a semiconductor device according to claim 2, further comprising the steps of:
removing said coating layer covering said interconnection layer; and
forming a barrier layer covering said interconnection layer.

5. The method of manufacturing a semiconductor device according to claim 1, further comprising the steps of:
forming a second insulation layer so as to cover said coating layer covering said interconnection layer and one electrode of said capacitor;
forming an upper interconnection hole and a hole for forming the other electrode in said second insulation layer;
filling said upper interconnection hole with a conductor containing copper to form an upper interconnection layer; and
filling said hole for forming the other electrode with the conductor containing copper to form the other electrode of said capacitor,
wherein said step of filling said upper interconnection hole with the said conductor containing copper to form said upper interconnection layer and said step of filling said hole for forming the other electrode with the said conductor containing copper to form the other electrode of said capacitor are performed in a single process step.

6. A semiconductor device including an interconnection and a capacitor, wherein
said interconnection and one electrode of said capacitor are both formed of a conductor containing copper; and
a barrier layer formed to cover said interconnection and a dielectric layer of said capacitor are formed with the same layer.

7. A semiconductor device including an interconnection and a capacitor, wherein
said interconnection and one electrode of said capacitor are both formed of a conductor containing copper; and
a barrier layer formed to cover said interconnection and a dielectric layer of said capacitor are formed with layers different from each other.

8. The semiconductor device according to claim 6, comprising an interconnection hole in which said interconnection has been formed, and a capacitor hole in which said capacitor has been formed,
wherein a volume of said interconnection hole is smaller than a volume of said capacitor hole.

9. The semiconductor device according to claim 6, comprising a capacitor hole in which said capacitor has been formed,
wherein said capacitor hole has a first portion and a second portion which have diameters different from each other, and
a diameter of said capacitor hole changes discretely at a boundary between said first portion and said second portion.
